(19) United States
(12) Patent Application Publication
(10) Pub. No.: US 2024/0222073 A1
(43) Pub. Date: Jul. 4, 2024

(54) ION BEAM LITHOGRAPHY AND NANOENGINEERING

(71) Applicant: Intel Corporation, Santa Clara, CA (US)

(72) Inventors: Shida Tan, Saratoga, CA (US); Uygar Avci, Portland (CA); Brandon Holybee, Portland, OR (US); Kirby Maxey, Hillsboro, OR (US); Kevin O'Brien, Portland, OR (US); Mahmut Sami Kavrik, Eugene, OR (US)

(21) Appl. No.: 18/147,636

(22) Filed: Dec. 28, 2022

(51) Int. Cl. H01J 37/317; H01L 21/027; H01L 21/033; H01L 21/311; H01L 21/3213

(52) U.S. Cl. CPC H01J 37/3174; H01L 21/0279; H01L 21/0332; H01L 21/0337; H01L 21/31122; H01L 21/31138; H01L 21/31144; H01L 21/32135; H01L 21/32139; H01J 2237/3174; H01J 2237/31755

(57) ABSTRACT

This disclosure describes systems, apparatus, methods, and devices related to ion beams fabrication. A device may overlay a wafer assembly of one or more layers with a top layer comprised of a material having 2D material characteristics. The device may be fabricated by applying an ion beam targeted to at least one of one or more regions of the top layer or a resist layer placed on top of the top layer, wherein the ion beam is tuned using a predetermined energy range or a dosing level of ions to modify material characteristics of the resist layer or to perform milling of the top layer or other layers of the one or more layers of the wafer assembly.

### TECHNICAL FIELD

This disclosure generally relates to systems, apparatus, and methods for semiconductor device fabrication and, more particularly, to ion beam lithography and nanoengineering.

### BACKGROUND

Traditional scaling in silicon-based transistors is becoming less common due to physical limitations. 2D materials, specifically transition metal dichalcogenide (TMD), may be a silicon replacement in a transistor. However, implementation of TMDs into next-generation transistors is precluded due to high contact resistance between metals and TMDs. In addition, the absence of a viable process to form n and p-type channels from TMDs are another major problem for TMD-based transistors.

### BRIEF DESCRIPTION OF THE DRAWINGS

FIGS. 1A-1F depict illustrative schematic diagrams for nano-patterning of TMDs with resist and ion, in accordance with one or more example embodiments of the present disclosure.

FIGS. 2A-2C depict illustrative schematic diagrams for direct patterning of TMDs with ion milling, in accordance with one or more example embodiments of the present disclosure.

FIGS. 3A-3E depict illustrative schematic diagrams for isolation of devices and routing metal connections with direct patterning using ion milling, in accordance with one or more example embodiments of the present disclosure.

FIG. 4 illustrates a flow diagram of a process for an illustrative of ion beams usage in device fabrication system, in accordance with one or more example embodiments of the present disclosure.

Certain implementations will now be described more fully below with reference to the accompanying drawings, in which various implementations and/or aspects are shown. However, various aspects may be implemented in many different forms and should not be construed as limited to the implementations set forth herein; rather, these implementations are provided so that this disclosure will be thorough and complete and will fully convey the scope of the disclosure to those skilled in the art. Like numbers in the figures refer to like elements throughout. Hence, if a feature is used across several drawings, the number used to identify the feature in the drawing where the feature first appeared will be used in later drawings.

### DETAILED DESCRIPTION

The following description and the drawings sufficiently illustrate specific embodiments to enable those skilled in the art to practice them. Other embodiments may incorporate structural, logical, electrical, process, algorithm, and other changes. Portions and features of some embodiments may be included in, or substituted for, those of other embodiments. Embodiments set forth in the claims encompass all available equivalents of those claims.

Transition-metal dichalcogenides (TMDs) and other 2D materials such as graphene, hexagonal boron nitride have extraordinary thin, robust structure with excellent transport properties which make them promising field effect transistor candidates for future semiconductor processes. TMD is being investigated as a Silicon (Si) replacement in recent years. However, traditional E-beam and immersion lithography process cause irreversible damage to TMDs chemical structures and degrade the device performance during the nanofabrication process.

2D material may include insulators, semiconductors, semimetals, and conductors, as well as their heterostructures. Some examples of 2D materials may include transition metal dichalcogenides, graphene family, 2D chalcogenides, 2D oxides, etc. Examples of 2D material may include, but not limited to, Graphene family (e.g., Graphene, hBn, BCN, Fluorographene, Graphene Oxide, etc.), 2D Chalcogenides (e.g., MoS2, WS2, MoSe2, WSe2, Semiconducting dichalcogenides, Metal Dichalcogenides, Layered semiconductors, etc.), 2D oxides (Micas BSCCO, MoO3, WO3, Layered Cu oxides, TiO2, MnO2, V2O5, TaO3, RuO2, Perovskite-type, Hydroxides, etc.). The 2D materials may be monolayer or multi-layers.

Conventional electron beam (e-beam) lithography is used to fabricate devices, but it does not solve the problem. E-beam lithography induces chalcogen (S, Se or Te, atoms) vacancies in TMDs and degrades its electronic properties. Therefore, there is a need to develop a mechanism to preserve the electronic properties of TMDs and other 2D materials in wafer applications.

Implementation of 2D material in FET/FeFET is precluded prominently by the contact resistance emerging from materials-inherent defects. While the origin of these defects is yet to be understood, reports in literature suggests defects induced during 2D material growth as well as deterioration of 2D materials by creation of S or Se vacancies by fabrication processes. In addition to this, formation of interlayer carbon between 2D material and S/D contact metal by residual carbon induced from lithography impedes current flow. It is critical to develop a process to address these problems for implementation of 2D materials in transistors.

Example embodiments of the present disclosure relate to systems, methods, and devices for ion beam lithography and nanoengineering for Novel semiconductor device nanofabrication

In one or more embodiments, an ion beam may be used to fabricate semiconductor devices through either ion beam lithography (via patterning resist) or direct ion beam nano-patterning. Some example of ion beams may include ion beams of helium, neon, nitrogen, oxygen, argon, xenon, etc. For example, helium and/or neon (hereinafter referred to as “He+/Ne+” or “He/Ne ion”) can be used to pattern the resist as well as directly mill the target materials with a high degree of precision. In this disclosure, helium and/or neon are used for illustrative purposes, but other types of ion beams may be used.

Ion beams lithography, such as helium ion beam lithography (HIBL) and neon ion beam lithography (NIBL) resolution are better than that of standard photo-based lithography techniques and comparable to that of high-performing e-beam lithography (EBL) systems. The ion beam material interaction volume is smaller than that of an electron beam at an equivalent energy, and thus shorter-range proximity effects relative to the electrons. More importantly, as an example, the hydrogen silsesquioxane (HSQ) resist is over four times more sensitive to He+ ions in comparison to electrons. HIBL has also been used to induce cross-linking of aromatic self-assembled monolayers to form carbon membranes with a 60 times improvement in exposure efficiency compared to EBL processes. In addition, HIBL and NIBL are distinctively capable of direct patterning lines with sub-10 nm line width even within the current limitation of the technology. HIBL and NIBL are crucial to manufacture next generation transistors using TMDs by enabling damage free lithographic patterning of them preventing degradation of TMDs thus deterioration of transistors.

In one or more embodiments, an ion beam assisted fabrication system may facilitate ion beam induced direct write lithography and nano-patterning enabled rapid device prototyping processes. Such technology implemented at the wafer scale could enable large scale deployment of TMD based devices. Such capabilities are available in small chamber level tools; however, the operation is limited within a narrow landing energy range (e.g. 5 to 30 keV) for device prototyping proof of concept.

In one or more embodiments, to be able to accomplish high volume manufacturing of TMDs based transistors, a new type of ion irradiation platform for die level and or wafer level nanofabrication needs to be developed. The platform needs to be equipped with high precision lithography level ion beam patterning source and beam-line and stage navigation capabilities.

In one or more embodiments, the ion beam technology includes but is not limited to light element noble gas ion sources, plasma ion sources, cold ion sources. The beam landing energy range should be tunable over a large energy range (e.g., from 1 to 100 keV) to achieve the desirable nanomachining, implantation, and lithography outcome.

The above descriptions are for purposes of illustration and are not meant to be limiting. Numerous other examples, configurations, processes, algorithms, etc., may exist, some of which are described in greater detail below. Example embodiments will now be described with reference to the accompanying figures.

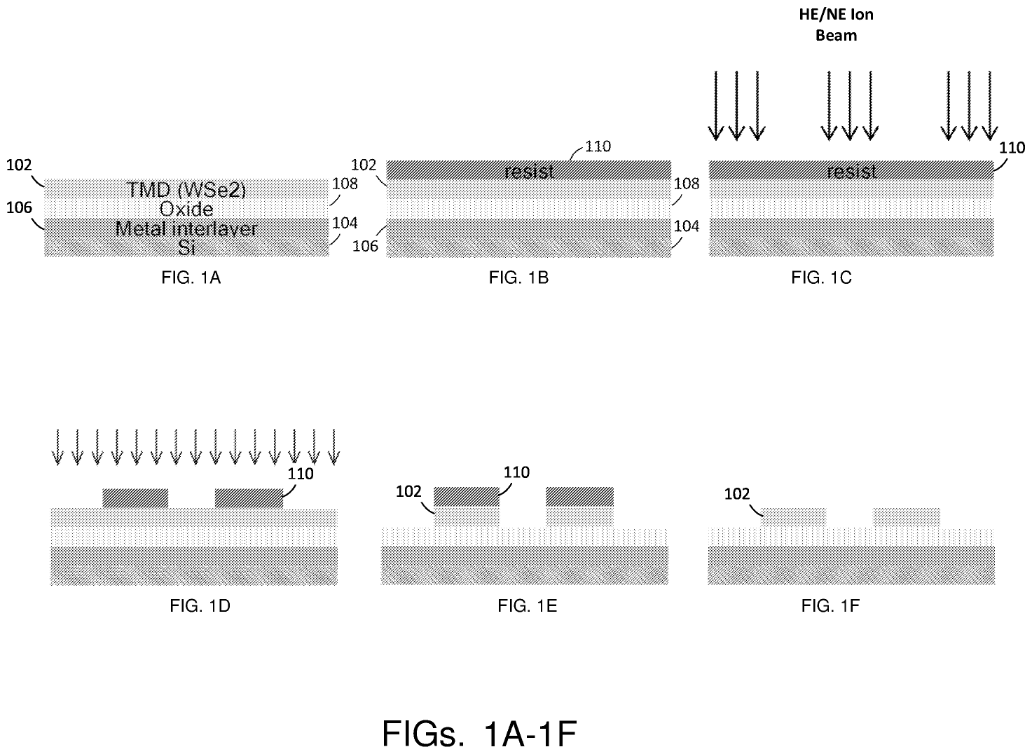

FIGS. 1A-1F depict illustrative schematic diagrams for nano-patterning of TMDs with resist and ion, in accordance with one or more example embodiments of the present disclosure.

Referring to FIG. 1A, there is shown a 2D material 102 (e.g., TMD) on a substrate that is comprised of a silicone layer 104, a metal interlayer 106, and an oxide layer 108. It should be understood that other layers may be included in the substrate.

Referring to FIG. 1B, there is shown the application/coating of a resist (can be between 1 nm to 500 nm) layer 110 on top of the 2D material 102. The resist layer 110 may be coated for lithograph.

Referring to FIG. 1C, there is shown the patterning of the resist layer 110 using ion beams (e.g., helium, neon, nitrogen, oxygen, argon, xenon, etc., ion beams). The ion beams may be applied in a desired pattern targeting certain region of the resist layer 110.

Referring to FIG. 1D, there is shown performing dry etching that removes the regions of the 2D layer defined by patterned resists 110 that were targeted by the ion beams in FIG. 1C.

Referring to FIG. 1E, there is shown the removed region of the 2D layer and the patterning resist. The removal of the remaining resist layer may be achieved using solvent cleaning or the use of H—N plasma or other means to remove portions of the resist layer 110.

Referring to FIG. 1F, there is shown the exposed 2D material after the removal of the certain regions of the resist layer 110. The exposed 2D material is patterned based on the application of the ion beams that targeted those regions, which ultimately resulted in the removal of portions of the 2D material 102 to result in a predetermined pattern.

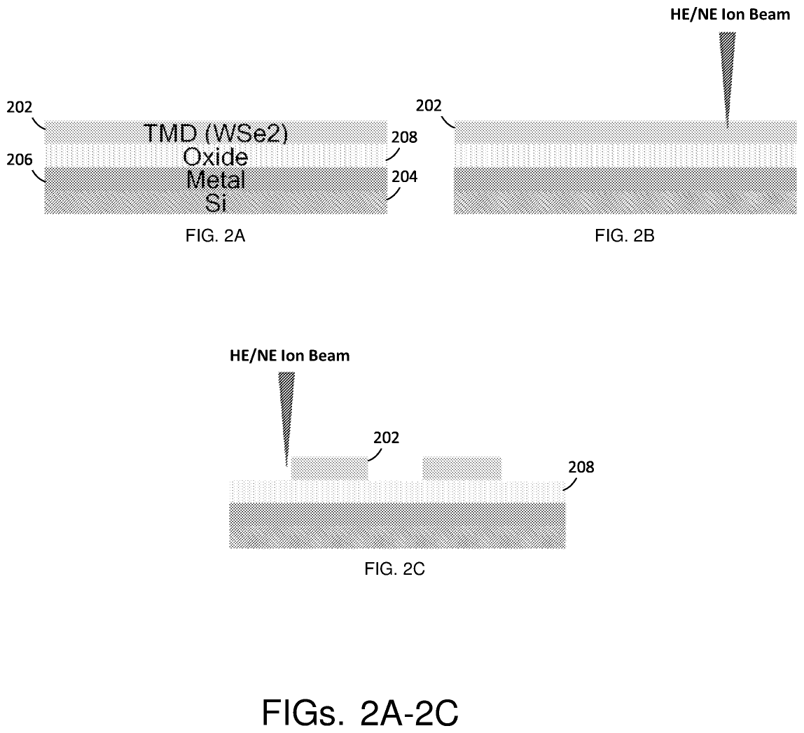

FIGS. 2A-2C depict illustrative schematic diagrams for direct patterning of TMDs with ion milling, in accordance with one or more example embodiments of the present disclosure.

Referring to FIG. 2A, there is shown a 2D material 202 (e.g., TMD) on a substrate that is comprised of a silicone layer 204, a metal interlayer 206, and an oxide layer 208.

Referring to FIG. 2B, there is shown the use of ion beams (e.g., helium, neon, nitrogen, oxygen, argon, xenon, etc., ion beams) to perform milling based a predetermined pattern. As the ion beams impact the top layer (2D material layer 202), the ion beams result in removing portions or regions of the 2D material 202 (top layer) to expose a patterned 2D (shown in FIG. 2C).

It is understood that the above descriptions are for purposes of illustration and are not meant to be limiting.

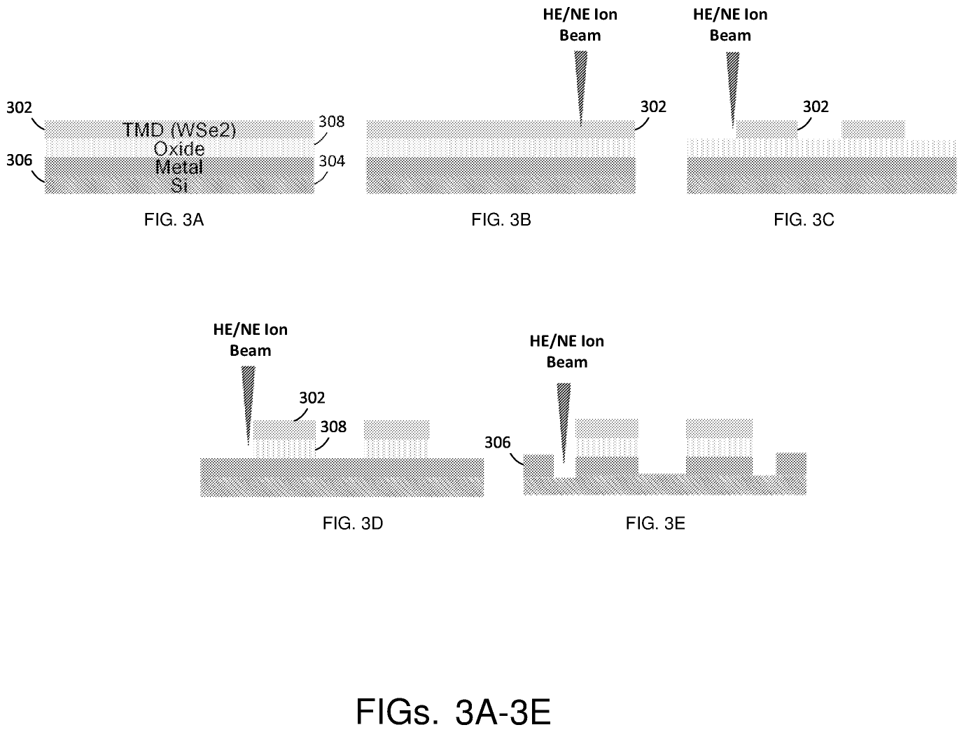

FIGS. 3A-3E depict illustrative schematic diagrams for isolation of devices and routing metal connections with direct patterning using ion milling, in accordance with one or more example embodiments of the present disclosure.

Referring to FIG. 3A, there is shown a 2D material 302 (e.g., TMD) on a substrate that is comprised of a silicone layer 304, a metal interlayer 306, and an oxide layer 308.

Referring to FIG. 3B, there is shown the use of ion beams (e.g., helium, neon, nitrogen, oxygen, argon, xenon, etc. ion beams) to perform milling based a predetermined pattern. As the ion beams impact the top layer (2D material layer), the ion beams result in removing portions of the top layer to expose a patterned 2D (shown in FIG. 3C).

Referring to FIG. 3D, there is shown the isolation or removal of portions of the oxide layer 308 using additional exposure of that layer with the ion beams in order to create a pattern. In this figure, it is seen that portions of the oxide layer 308 were removed in order for the remaining portions to mimic those of the remaining 2D material layer 302.

Referring to FIG. 3E, there is shown additional milling using the ion beams to remove portions of the metal interlayer 306. The purpose is to expose specific patterns with direct patterning using ion milling.

It is understood that the above descriptions are for purposes of illustration and are not meant to be limiting.

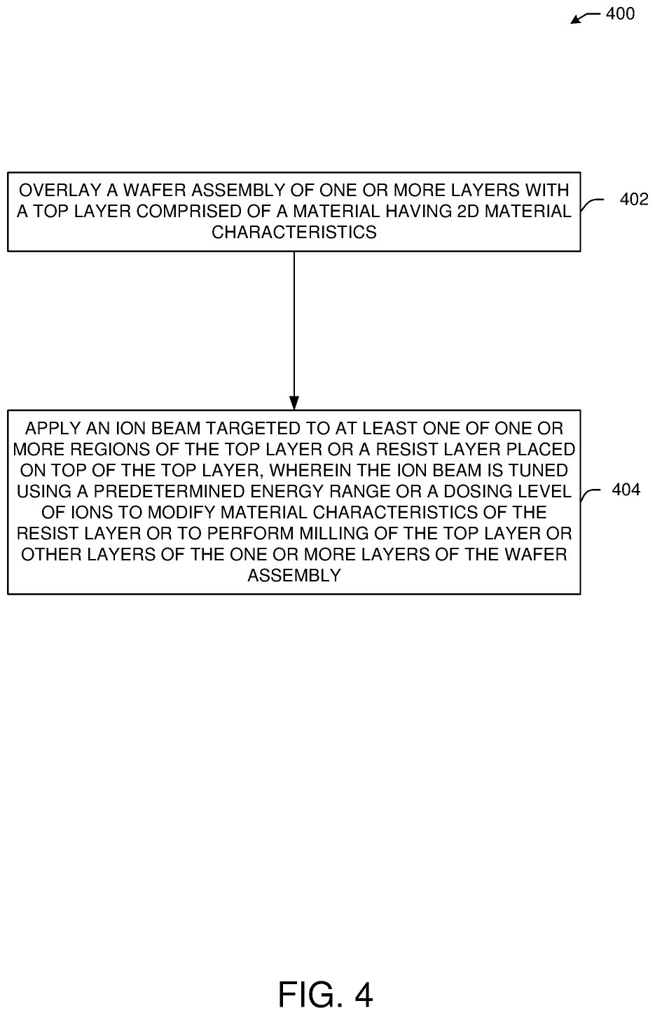

FIG. 4 illustrates a flow diagram of a process 400 for an ion beams fabrication system, in accordance with one or more example embodiments of the present disclosure.

The process may include, at block 402, overlaying a wafer assembly of one or more layers with a top layer comprised of a material having 2D material characteristics.

The process may include, at block 404, applying an ion beam targeted to at least one of one or more regions of the top layer or a resist layer placed on top of the top layer, wherein the ion beam is tuned using a predetermined energy range or a dosing level of ions to modify the material characteristics of the resist layer or to perform milling of the top layer or other layers of the one or more layers of the wafer assembly.

It is understood that the above descriptions are for purposes of illustration and are not meant to be limiting.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software, and/or firmware.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

The operations and processes described and shown above may be carried out or performed in any suitable order as desired in various implementations. Additionally, in certain implementations, at least a portion of the operations may be carried out in parallel. Furthermore, in certain implementations, less than or more than the operations described may be performed.

The word “exemplary” is used herein to mean “serving as an example, instance, or illustration.” Any embodiment described herein as “exemplary” is not necessarily to be construed as preferred or advantageous over other embodiments.

As used herein, unless otherwise specified, the use of the ordinal adjectives “first,” “second,” “third,” etc., to describe a common object, merely indicates that different instances of like objects are being referred to and are not intended to imply that the objects so described must be in a given sequence, either temporally, spatially, in ranking, or any other manner.

Although specific embodiments of the disclosure have been described, one of ordinary skill in the art will recognize that numerous other modifications and alternative embodiments are within the scope of the disclosure. For example, any of the functionality and/or processing capabilities described with respect to a particular device or component may be performed by any other device or component. Further, while various illustrative implementations and architectures have been described in accordance with embodiments of the disclosure, one of ordinary skill in the art will appreciate that numerous other modifications to the illustrative implementations and architectures described herein are also within the scope of this disclosure.

Although embodiments have been described in language specific to structural features and/or methodological acts, it is to be understood that the disclosure is not necessarily limited to the specific features or acts described. Rather, the specific features and acts are disclosed as illustrative forms of implementing the embodiments. Conditional language, such as, among others, “can,” “could,” “might,” or “may,” unless specifically stated otherwise, or otherwise understood within the context as used, is generally intended to convey that certain embodiments could include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes overlaying a wafer assembly of one or more layers with a top layer may include of a 2D material. The overlaying also includes depositing a resist layer on top of the top layer. The overlaying also includes applying an ion beam targeted to one or more regions of the resist layer. The overlaying also includes performing dry etching on the resist layer. Other embodiments of this aspect include corresponding computer systems, apparatus, and computer programs recorded on one or more computer storage devices, each configured to perform the actions of the methods.

Implementations may include one or more of the following features. The method may include removing the one or more regions of the resist layer that were targeted by the ion beam. The method may include applying solvent to remove remaining regions of the resist layer. The method may include exposing a pattern of the top layer after removal of the remaining regions of the resist layer. The method may include performing milling using the ion beam targeting the top layer to create a predetermined pattern. The method may include performing milling using the ion beam targeting exposed oxide layer. The method may include performing milling using the ion beam targeting exposed metal layer. The ion beam is a helium or a neon beam. The top layer is a tdm layer. The one or more layers of the wafer assembly may include an oxide layer, a metal layer, or a silicon layer. Implementations of the described techniques may include hardware, a method or process, or computer software on a computer-accessible medium.

One general aspect includes a system for fabricating a semiconductor package. The system also includes overlay a wafer assembly of one or more layers with a top layer may include of a 2D material. The system also includes deposit a resist layer on top of the top layer. The system also includes apply an ion beam targeted to one or more regions of the resist layer. The system also includes perform dry etching on the resist layer. Other embodiments of this aspect include corresponding computer systems, apparatus, and computer programs recorded on one or more computer storage devices, each configured to perform the actions of the methods.

Implementations may include one or more of the following features. The system where the instructions further may include removing the one or more regions of the resist layer that were targeted by the ion beam. The instructions further may include applying solvent to remove remaining regions of the resist layer. The instructions further may include exposing a pattern of the top layer after removal of the remaining regions of the resist layer. The instructions further may include performing milling using the ion beam targeting the top layer to create a predetermined pattern. The instructions further may include performing milling using the ion beam targeting exposed oxide layer. The instructions further may include performing milling using the ion beam targeting exposed metal layer. The ion beam is a helium or a neon beam. Implementations of the described techniques may include hardware, a method or process, or computer software on a computer-accessible medium.

One general aspect includes a semiconductor fabrication device. The semiconductor fabrication device also includes overlay a wafer assembly of one or more layers with a top layer may include of a 2D material. The device also includes deposit a resist layer on top of the top layer. The device also includes apply an ion beam targeted to one or more regions of the resist layer. The device also includes perform dry etching on the resist layer. Other embodiments of this aspect include corresponding computer systems, apparatus, and computer programs recorded on one or more computer storage devices, each configured to perform the actions of the methods.

Implementations may include one or more of the following features. The device where the operations further may include remove the one or more regions of the resist layer that were targeted by the ion beam. Implementations of the described techniques may include hardware, a method or process, or computer software on a computer-accessible medium.

One general aspect includes the device, other embodiments of this aspect include corresponding computer systems, apparatus, and computer programs recorded on one or more computer storage devices, each configured to perform the actions of the methods.

Embodiments according to the disclosure are in particular disclosed in the attached claims directed to a method, a storage medium, a device and a computer program product, wherein any feature mentioned in one claim category, e.g., method, can be claimed in another claim category, e.g., system, as well. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

The foregoing description of one or more implementations provides illustration and description, but is not intended to be exhaustive or to limit the scope of embodiments to the precise form disclosed. Modifications and variations are possible in light of the above teachings or may be acquired from practice of various embodiments.

Certain aspects of the disclosure are described above with reference to block and flow diagrams of systems, methods, apparatuses, and/or computer program products according to various implementations. It will be understood that one or more blocks of the block diagrams and flow diagrams, and combinations of blocks in the block diagrams and the flow diagrams, respectively, may be implemented by computer-executable program instructions. Likewise, some blocks of the block diagrams and flow diagrams may not necessarily need to be performed in the order presented, or may not necessarily need to be performed at all, according to some implementations.

These computer-executable program instructions may be loaded onto a special-purpose computer or other particular machine, a processor, or other programmable data processing apparatus to produce a particular machine, such that the instructions that execute on the computer, processor, or other programmable data processing apparatus create means for implementing one or more functions specified in the flow diagram block or blocks. These computer program instructions may also be stored in a computer-readable storage media or memory that may direct a computer or other programmable data processing apparatus to function in a particular manner, such that the instructions stored in the computer-readable storage media produce an article of manufacture including instruction means that implement one or more functions specified in the flow diagram block or blocks. As an example, certain implementations may provide for a computer program product, comprising a computer-readable storage medium having a computer-readable program code or program instructions implemented therein, said computer-readable program code adapted to be executed to implement one or more functions specified in the flow diagram block or blocks. The computer program instructions may also be loaded onto a computer or other programmable data processing apparatus to cause a series of operational elements or steps to be performed on the computer or other programmable apparatus to produce a computer-implemented process such that the instructions that execute on the computer or other programmable apparatus provide elements or steps for implementing the functions specified in the flow diagram block or blocks.

Accordingly, blocks of the block diagrams and flow diagrams support combinations of means for performing the specified functions, combinations of elements or steps for performing the specified functions and program instruction means for performing the specified functions. It will also be understood that each block of the block diagrams and flow diagrams, and combinations of blocks in the block diagrams and flow diagrams, may be implemented by special-purpose, hardware-based computer systems that perform the specified functions, elements or steps, or combinations of special-purpose hardware and computer instructions.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language is not generally intended to imply that features, elements, and/or operations are in any way required for one or more implementations or that one or more implementations necessarily include logic for deciding, with or without user input or prompting, whether these features, elements, and/or operations are included or are to be performed in any particular implementation.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense only and not for purposes of limitation.

What is claimed is:

1. A method for fabricating a semiconductor package comprising:
overlaying a wafer assembly of one or more layers with a top layer comprised of a material having 2D material characteristics; and
applying an ion beam targeted to at least one of one or more regions of the top layer or a resist layer placed on top of the top layer, wherein the ion beam is tuned using a predetermined energy range or a dosing level of ions to modify material characteristics of the resist layer or to perform milling of the top layer or other layers of the one or more layers of the wafer assembly.

2. The method of claim 1, wherein performing milling of the top layer or other layers of the one or more layers of the wafer assembly results in the removal of regions targeted by the ion beam.

3. The method of claim 1, wherein the resist layer prevents ion permeability to the top layer.

4. The method of claim 1, further comprising:
performing dry etching when the resist layer is applied and after applying the ion beam targeted to the one or more regions of the resist layer;
applying solvent to remove remaining regions of the resist layer.

5. The method of claim 1, wherein performing milling results in direct patterning of at least one of the one or more layers of the wafer assembly based on a predetermined pattern.

6. The method of claim 1, wherein the predetermined energy range is tunable from 1 to 100 keV to achieve a desirable nanomachining, implantation, and lithography outcome.

7. The method of claim 1, wherein the material is a monolayer or a multi-layer material.

8. The method of claim 1, wherein the ion beam comprises inert ion beams comprising at least one of helium, neon, nitrogen, oxygen, argon, or xenon.

9. The method of claim 1, wherein the top layer comprises at least one of transition metal dichalcogenide (TMD), Graphene, hBn, BCN, Fluorographene, Graphene Oxide, MoS2, WS2, MoSe2, WSe2, Semiconducting dichalcogenides, Metallic Dichalcogenides, Layered semiconductors, Micas BSCCO, MoO3, WO3, Layered Cu oxides, TiO2, MnO2, V2O5, TaO3, RuO2, Perovskite-type, or Hydroxides.

10. The method of claim 1, wherein the one or more layers of the wafer assembly comprises at least one of an oxide layer, a metal layer, or a silicon layer.

11. A system for fabricating a semiconductor package, the system comprising computer-executable instructions to:
overlay a wafer assembly of one or more layers with a top layer comprised of a material having 2D material characteristics;
apply an ion beam targeted to at least one of one or more regions of the top layer or a resist layer placed on top of the top layer, wherein the ion beam is tuned using a predetermined energy range or a dosing level of ions to modify material characteristics of the resist layer or to perform milling of the top layer or other layers of the one or more layers of the wafer assembly.

12. The system of claim 11, wherein performing milling of the top layer or other layers of the one or more layers of the wafer assembly results in the removal of regions targeted by the ion beam.

13. The system of claim 11, wherein the resist layer prevents ion permeability to the top layer.

14. The system of claim 11, wherein the instructions further comprise:
perform dry etching when the resist layer is applied and after applying the ion beam targeted to the one or more regions of the resist layer;
apply solvent to remove remaining regions of the resist layer.

15. The system of claim 11, wherein the instructions further comprise exposing a pattern of the top layer after removal of the remaining regions of the resist layer.

16. The system of claim 11, wherein performing milling results in direct patterning of at least one of the one or more layers of the wafer assembly based on a predetermined pattern.

17. The system of claim 11, wherein the predetermined energy range is tunable from 1 to 100 keV to achieve a desirable nanomachining, implantation, and lithography outcome.

18. The system of claim 11, wherein the ion beam comprises inert ion beams comprising at least one of helium, neon, nitrogen, oxygen, argon, or xenon.

19. The system of claim 11, wherein the top layer comprises at least one of transition metal dichalcogenide (TMD), Graphene, hBn, BCN, Fluorographene, Graphene Oxide, MoS2, WS2, MoSe2, WSe2, Semiconducting dichalcogenides, Metallic Dichalcogenides, Layered semiconductors, Micas BSCCO, MoO3, WO3, Layered Cu oxides, TiO2, MnO2, V2O5, TaO3, RuO2, Perovskite-type, or Hydroxides.

20. A semiconductor fabrication device, the device comprising processing circuitry coupled to storage, the processing circuitry configured to:
overlay a wafer assembly of one or more layers with a top layer comprised of a material having 2D material characteristics;
apply an ion beam targeted to at least one of one or more regions of the top layer or a resist layer placed on top of the top layer, wherein the ion beam is tuned using a predetermined energy range or a dosing level of ions to modify material characteristics of the resist layer or to perform milling of the top layer or other layers of the one or more layers of the wafer assembly.
